(19) United States
(12) Patent Application Publication
(10) Pub. No.: US 2012/0328882 A1
(43) Pub. Date: Dec. 27, 2012

(54) INFUSING A POROUS MEDIA WITH AN ACTIVE CHEMICAL AGENT VAPOR

(75) Inventors: John M. Forsythe, Nampa, ID (US); Henry John Duncan, Glasgow (GB); Curtis Lee Eames, Meridian, ID (US)

(73) Assignee: 1,4 GROUP, INC., Meridian, ID (US)

(21) Appl. No.: 13/530,867

(22) Filed: Jun. 22, 2012

Related U.S. Application Data
(60) Provisional application No. 61/499,758, filed on Jun. 22, 2011.

(51) Int. Cl. C23C 16/44; B32B 5/16

(52) U.S. Cl. 428/403; 427/248.1; 427/255.6

(57) ABSTRACT

Porous media may be infused with a layer of chemical upon an extended surface of the porous media by forming a vapor of the chemical and condensing the vapor onto exposed surfaces of the porous media.

### CROSS-REFERENCE TO RELATED APPLICATION

This application claims the benefit of U.S. Provisional Patent Application Ser. No. 61/499,758, filed Jun. 22, 2011, the disclosure of which is hereby incorporated herein in its entirety by this reference.

### TECHNICAL FIELD

A porous media with an extended surface area containing an active chemical agent which is useful for passive treatment for stored crops via sublimation/evaporation of the active chemical agent from the extended surface of the porous media.

### BACKGROUND OF INVENTION

Various liquid volatile chemicals have been incorporated with porous inorganic media by soaking the media in the liquid chemical, then draining off the excess liquid. Tecnazene, a solid at room temperature, has been melted and mixed with alumina. Generally, these methods and chemicals have been used for experimental procedures. U.S. Pat. No. 5,918,537 disclosed a device containing porous media impregnated with dimethyl naphthalene. The patent further references prior articles setting forth the state of the art with reference to impregnated porous media.

Loose granules of clay mixed with CIPC have been used with respect to commercial storage of potatoes. Direct contact of potatoes, especially when freshly dug and damp, with CIPC tends to damage the potatoes. Also, use of clays as media tends to absorb moisture causing them to stick to the potatoes, generally presenting a clean-up problem when the potatoes are removed from storage (see U.S. Pat. No. 5,849,664).

CIPC, upon melting, forms a waxy, viscous material. Mixing of alumina or other inorganic particles, having an extended surface area, with molten CIPC tends to coat the exterior of the particles without infusing much of the CIPC into the interior extended skeletal surface of such minute particles. In order to effectuate good sprout inhibition via sublimation from solid CIPC, the CIPC surface area must be very large. Thus, unless the extensive interior area of porous inorganic media, such as alumina, is coated with CIPC, then a large amount of such media must be used and surface contact between the media and the potatoes generally must be avoided.

### BRIEF DESCRIPTION OF THE DRAWING

FIG. 1 is a schematic drawing illustrating a system for infusing porous media.

### DETAILED DESCRIPTION OF THE INVENTION

One effective technique for coating the extended surface of a porous media is by forming a vapor of the active chemical agent and then condensing said vapor onto the extended surface of said porous media.

A vapor of the active chemical agent may be formed by heating the active chemical agent above its boiling point. The vapor may then be contacted with porous media to condense said vapor upon the extended surface of said porous media to form a thin coating thereon. The porous media is preferably at a temperature below the melting point of active chemical agent whenever CIPC, for example, is said agent.

In treating a porous agent with CIPC vapor, the CIPC may be molten with dry air passed through the molten CIPC to carry its vapor to the porous media. Any vapor not condensed upon the porous media is passed through a recycle condenser to condense the CIPC vapor to a liquid (molten) state to be recycled back to a CIPC vaporization pot.

Another technique for forming a vapor of CIPC is to boil CIPC under a vacuum at a temperature well below its decomposition temperature of about 450° F. Such vapor is then condensed upon porous media at a temperature below its melting point of about 105° F. The porous media is also under the same vacuum system as the vaporization pot. Any vapor not condensed upon said porous media passes through a recycle condenser, also under vacuum, to recycle liquid CIPC to the vaporization pot. Hot, dry air introduced into the vaporization pot is ultimately exhausted from the vacuum pump used to put the whole system under a preferred reduced pressure (vacuum).

Coating of porous media from CIPC vapor is preferably a batch-wise process whereby the vapor is discontinued and the porous media with a very thin coating of active chemical agent, e.g., CIPC, is discharged into a shipping container. During discharge of the porous media into a shipping container, vapor from the vaporization pot may be recycled through a by-pass line to the vapor condenser to recycle condensed liquid to the vaporization pot.

An advantage of coating the extended surface of a porous media, especially porous media such as silica gel, alumina, diatomaceous earth, natural zeolites and the like, is that a chemical agent in vapor form will penetrate into the smallest of pores to coat the interior surface of such media. The large extended surface of inorganic media, such as silica gel and alumina, is provided within the skeleton-like lattice of such media. The surface pore openings into such interior lattice are small. An optimal coating of solid CIPC, e.g., on such extended surface may be only one or two molecules in thickness. Such an optimal coating may be achieved by exposing the porous media to CIPC vapor, especially if said vapor is diluted by hot, dry air to minimize condensation of large droplets at a pore opening, which could result in undesirable plugging of the pore at its surface opening. Given that most porous inorganic media are very hydroscopic, it is desirable that any air introduced into the vaporization pot be extremely dry, otherwise water can condense upon the extended surface of the porous media which will generally preclude condensation of CIPC upon that surface since CIPC is hydrophobic.

Because of the strong hydroscopic nature of inorganic porous media, it is preferable to thoroughly dry such media before exposure to vapor of an active chemical agent, such as CIPC.

Although the coating process described herein has been with reference to CIPC, it is also effective for other chemical agents having some insecticidal, bactericidal, fungicidical, and/or herbicidal activity, from either a liquid or solid state, provided that a thin coating of such agent is on a substantial portion of the extended surface of the porous media. Such porous media may then be used as a passive system to treat stored crops via evaporation or sublimation of the chemical agent from the extended coated surface of said media.

Examples of other herbicide/sprout inhibitors besides CIPC include, but are not limited to, dimethyl naphthalene (DMN), diisopropyl naphthalene (DIPN), essential oils (such as carvone, clove oil, lemongrass oil, citronellol, peppermint oil and the like), and various alcohols, such as C6-C10 alcohols such as nonanol and various conjugated alcohols.

Crops that may be treated with such passive systems include stored potatoes, onions and similar tubers to prevent unwanted sprouting and an even wider variety of stored crops to be treated with pesticides, fungicides, etc.

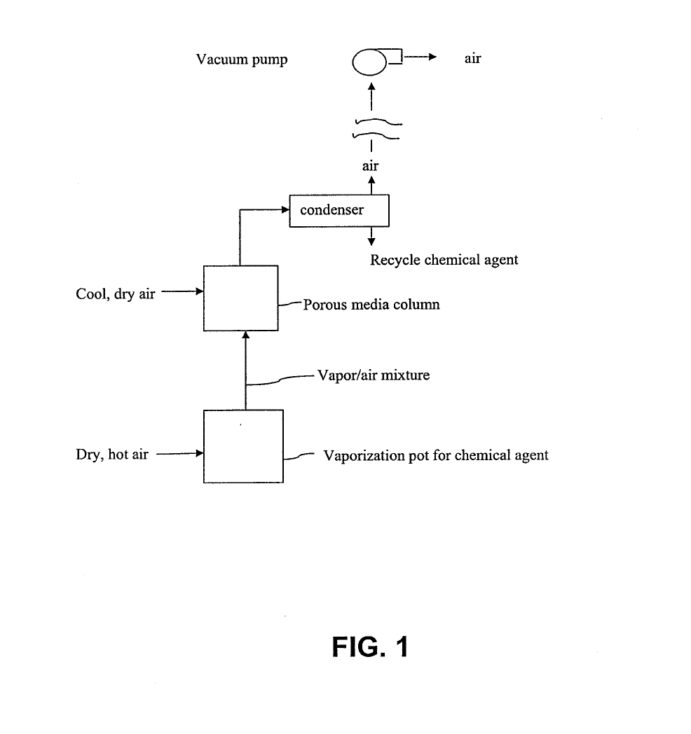

FIG. 1 illustrates an embodiment of a system for infusing porous media, especially inorganic porous media, with a thin coating of a solid chemical agent via exposure of such media to vapors of said chemical agent.

A chemical agent is introduced into a vaporization/melting pot. Dry, hot air may also be introduced to assist in the vaporization of said chemical agent, especially if such vaporization is conducted below the normal boiling point of said chemical agent. The vapor can be introduced to the porous media for a sufficient period of time to permit the vapors to penetrate thoroughly the interior surfaces of the porous media. The porous media may be initially chilled (i.e., at a temperature below the condensation temperature of the vapors) or the media may be later cooled by introduction of dry cool air into contact with the porous media.

By way of example, vapors of CIPC may be initially condensed upon the porous media at a temperature sufficiently elevated such that the CIPC coating becomes a non-viscous liquid which is subsequently cooled to a thin solid coating. Having the porous media too cool initially could potentially cause condensation of viscous CIPC only on the external/exterior surface of the porous media. Thus, allowing penetration of vapor or non-viscous liquid to penetrate into the interior surfaces of the porous media is generally preferred.

As illustrated in FIG. 1, dry cool air may be introduced into contact with the porous media to cool it initially or subsequently after the vapor/non-viscous liquid has effectively penetrated into the interior surfaces of the porous media.

A mixture of air and vapor exiting from the porous media column can be passed through a condenser to condense the chemical agent to a liquid state to be returned to the vaporization pot. Air can be vented from the condenser, which occurs through an exhaust fan or through a vacuum pump if the system has been operated under reduced pressure.

The system is preferably operated as a batch process whereby the coated, cooled porous media is transferred to a storage tank where it may be further cooled before transfer to a shipping container.

A vapor coating system, such as that described herein, may effectively coat in excess of 50% of the available surface of the porous media. Also, since vapors of the chemical agent are condensed and recycled to the vaporization pot, no significant amount of chemical agent vapor is lost to the external atmosphere. Because of toxicity concerns with some chemical agents, the described system is environmentally friendly.

Besides silica gel and alumina, other inorganic porous media having large extended surfaces per unit volume and per unit weight that are suitable for use include diatomaceous earth, naturally occurring zeolites, and the like. It is understood that any suitable porous media known in the art may be employed in the practice of the invention.

Preferred porous media are those which are not affected by the high temperatures of the chemical agent vapors. Vapor temperature may be controlled by vaporization under reduced pressure or vaporization at temperatures below the boiling point of the chemical agent.

Substantially pure chemical agents can be infused into porous inorganic media by the techniques described herein. Also, mixtures of chemical agents may be infused into a porous inorganic media. For example, a solution of CIPC in 1,4 DMN can be evaporated to provide a coating that is a mixture of these chemicals. Because 1,4 DMN is more volatile and has a lower molecular weight than CIPC, the vapor concentration of each will be different than the weight concentration of each in a solution that is vaporized.

A coating of a mixture of 1,4 DMN and CIPC upon the extended surface of a porous inorganic media may have advantageous effects as sprout inhibitors for potatoes. Riggle et al., U.S. Pat. No. 5,622,912 reports a synergistic effect for such mixtures applied via an aerosol technique.

Other vapor mixtures may be condensed upon the porous media described herein. Mixtures of CIPC with carvone, for example, may have particular utility when condensed as a sprout inhibiting coating. See U.S. Pat. No. 5,811,372. Carvone is a registered sprout inhibitor (herbicide) in many European countries.

Another technique for forming mixed coatings upon a porous media includes application of the coatings sequentially. For example, a coating of CIPC could be deposited first upon the extended surface of a porous inorganic media followed thereafter by the vapor deposition of 1,4 DMN. Although 1,4 DMN is a solvent for CIPC, the solubility of CIPC in 1,4 DMN at low temperatures is limited. Thus, at the condensation temperature involved and at the potato storage temperatures (5° C. to 10° C.), the two films (coatings) would tend to remain separate with only some limited solubilization at the interface of the two coatings. Thus, the 1,4 DMN would tend to evaporate first in a potato storage facility, thereby, to some extent providing a delayed release of CIPC vapors. Such a system could be devised whereby significant sublimation of CIPC was delayed until after the stored potatoes had suberized even though the coated porous media was placed in the potato storage facility at the same time as the potatoes were stored therein.

What is claimed is:

1. A method of infusing porous media with a chemical comprising:
forming a vapor of said chemical; and
condensing said vapor onto an exposed surface of said porous media.

2. The method of claim 1, wherein said porous media is at a temperature that is below the dew point of the chemical vapor.

3. The method of claim 1, wherein said porous media is an inorganic media comprising at least one of silica gel and alumina.

4. The method of claim 1, wherein said porous media is an organic fibrous material.

5. The method of claim 1, wherein the chemical is chloroisopropyl carbamate (CIPC).

6. The method of claim 5, wherein said CIPC vapor is generated from a mass of molten CIPC.

7. The method of claim 6, wherein said molten CIPC is at a temperature less than its normal boiling point.

8. The method of claim 7, wherein said molten CIPC is under a reduced pressure.

9. The method of claim 6, wherein dry air is passed through or over said molten mass of CIPC.

10. The method of claim 1, wherein said porous media is chilled before contact by said vapor.

11. The method of claim 1, wherein said chemical is a mixture of chemicals.

12. The method of claim 1, wherein CIPC and 1,4 DMN are infused as a vapor mixture.

13. The method of claim 7, wherein CIPC vapor is first infused into a porous media and a second chemical is thereafter infused into said media.

14. The method of claim 13, wherein said second chemical is 1,4 DMN.

15. The method of claim 13, wherein said second chemical is carvone.

16. An inorganic porous media containing a coating of CIPC made according to the method of claim 1.
